(19) United States
(12) Patent Application Publication
(10) Pub. No.: US 2025/0227937 A1
(43) Pub. Date: Jul. 10, 2025

(54) MAGNETORESISTIVE RANDOM ACCESS MEMORY DEVICE

(71) Applicant: SAMSUNG ELECTRONICS CO., LTD., Suwon-si (KR)

(72) Inventors: Shinhee HAN, Suwon-si (KR); Kiseok SUH, Suwon-si (KR); Boyoung SEO, Suwon-si (KR); Kangho LEE, Suwon-si (KR)

(73) Assignee: SAMSUNG ELECTRONICS CO., LTD., Suwon-si (KR)

(21) Appl. No.: 18/953,936

(22) Filed: Nov. 20, 2024

(30) Foreign Application Priority Data
Jan. 4, 2024 (KR) 10-2024-0001668

(51) Int. Cl. H10B 61/00

(52) U.S. Cl. CPC H10B 61/10

(57) ABSTRACT

Provided is a magnetoresistive random access memory (MRAM) device including: a cell region on a substrate; a core peripheral region on the substrate and adjacent from the cell region in a horizontal direction; a first interlayer insulating layer in the cell region and the core peripheral region; a second interlayer insulating layer on the first interlayer insulating layer; a first interconnection line in the first interlayer insulating layer, wherein the first interconnection line is in the cell region and the core peripheral region; a second interconnection line in the second interlayer insulating layer, wherein the second interconnection line is in the core peripheral region and is connected to the first interconnection line; a lower electrode contact on the first interconnection line in the cell region; and a magnetic tunnel junction structure on the lower electrode contact, wherein the lower electrode contact and the second interconnection line overlap each other in a horizontal direction.

### CROSS-REFERENCE TO RELATED APPLICATION

This application is based on and claims priority to Korean Patent Application No. 10-2024-0001668, filed on Jan. 4, 2024, in the Korean Intellectual Property Office, the disclosure of which is incorporated by reference herein in its entirety.

### BACKGROUND

### 1. Field

The disclosure relates to a semiconductor device, and more particularly, to a magnetoresistive memory device, that is, a magnetoresistive random access memory (MRAM) device.

### 2. Description of Related Art

As electronic devices become faster and/or have lower power consumption, demands for higher speed and/or lower operating voltages for semiconductor devices included in electronic devices have increased. In order to meet these demands, MRAM devices have been proposed as semiconductor devices. MRAM devices are attracting attention as next-generation semiconductor devices because they can have characteristics such as high-speed operation and/or non-volatility.

In general, MRAM devices may include a magnetic tunnel junction. The magnetic tunnel junction may include two magnetic materials and an insulating layer sandwiched therebetween. The resistance value of the magnetic tunnel junction may vary depending on the magnetization directions of the two magnetic materials. For example, when the magnetization directions of the two magnetic materials are antiparallel to each other, the magnetic tunnel junction may have a large resistance value, and when the magnetization directions of the two magnetic materials are parallel to each other, the magnetic tunnel junction may have a small resistance value. Data may be written/read using the difference in resistance values.

As the electronics industry progresses, the demands for high integration and/or low power consumption for MRAM devices have intensified. Therefore, many studies have been conducted to meet these demands.

### SUMMARY

Provided is a magnetoresistive random access memory (MRAM) device having improved performance and reliability.

Further provided is an MRAM device having a simplified manufacturing process.

The disclosure is not limited to the problems mentioned above, and other problems not mentioned will be clearly understood by those skilled in the art from the description below.

According to an aspect of the disclosure, a magnetoresistive random access memory (MRAM) device includes: a cell region on a substrate; a core peripheral region on the substrate and adjacent from the cell region in a horizontal direction; a first interlayer insulating layer in the cell region and the core peripheral region; a second interlayer insulating layer on the first interlayer insulating layer; a first interconnection line in the first interlayer insulating layer, wherein the first interconnection line is in the cell region and the core peripheral region; a second interconnection line in the second interlayer insulating layer, wherein the second interconnection line is in the core peripheral region and is connected to the first interconnection line; a lower electrode contact on the first interconnection line in the cell region; and a magnetic tunnel junction structure on the lower electrode contact, wherein the lower electrode contact and the second interconnection line overlap each other in a horizontal direction.

According to an aspect of the disclosure, a magnetoresistive random access memory (MRAM) device includes: a cell region on a substrate; a core peripheral region on the substrate and adjacent from the cell region in a horizontal direction; a cell transistor in the cell region; a core peripheral transistor in the core peripheral region; a cell interconnection line in the cell region, wherein the cell interconnection line is connected to the cell transistor; a core peripheral interconnection line in the core peripheral region, wherein the core peripheral interconnection line is connected to the core peripheral transistor; a lower electrode contact connected to the cell interconnection line; and a magnetic tunnel junction structure on the lower electrode contact, wherein an upper surface of each of the cell interconnection line and the core peripheral interconnection line is at a vertical level that is the same as or lower than a vertical level of a lower surface of the magnetic tunnel junction structure, and wherein a vertical level of at least a portion of the core peripheral interconnection line overlaps a vertical level of the lower electrode contact.

According to an aspect of the disclosure, a magnetoresistive random access memory (MRAM) device includes: a cell region on a substrate; a core peripheral region on the substrate and adjacent from the cell region in a horizontal direction; a cell transistor in the cell region; a core peripheral transistor in the core peripheral region; a cell interlayer insulating layer on the cell transistor; a core peripheral interlayer insulating layer on the core peripheral transistor; a plurality of cell interconnection lines connected to the cell transistor; a plurality of core peripheral interconnection lines connected to the core peripheral transistor; a lower electrode contact on an uppermost cell interconnection line among the plurality of cell interconnection lines; an information storage structure on the lower electrode contact, the information storage structure including a lower electrode, a magnetic tunnel junction structure, and an upper electrode, wherein the lower electrode, the magnetic tunnel junction structure, and the upper electrode are sequentially stacked; and a bit line on the information storage structure, wherein the plurality of cell interconnection lines pass through the cell interlayer insulating layer at a vertical level that is the same as or lower than a vertical level of a lower surface of the magnetic tunnel junction structure, wherein the plurality of core peripheral interconnection lines pass through the core peripheral interlayer insulating layer at a vertical level that is same as or lower than the vertical level of the lower surface of the magnetic tunnel junction structure, and wherein the lower electrode contact overlaps an uppermost core peripheral interconnection line among the plurality of core peripheral interconnection lines in a horizontal direction.

### BRIEF DESCRIPTION OF DRAWINGS

The above and other aspects, features, and advantages of certain embodiments of the present disclosure will be more apparent from the following description taken in conjunction with the accompanying drawings, in which:

FIG. 1 is a circuit diagram of a unit memory cell of a magnetoresistive random access memory (MRAM) device according to one or more embodiments;

FIG. 2 is a cross-sectional view illustrating an MRAM device according to one or more embodiments;

FIG. 3 is a cross-sectional view illustrating an information storage structure of an MRAM device according to one or more embodiments;

FIGS. 4A and 4B are cross-sectional views illustrating examples of an information storage structure of an MRAM device according to one or more embodiments;

FIG. 5 is an enlarged cross-sectional view illustrating an area EX1 and an area EX2 of FIG. 2;

FIGS. 6, 7 and 8 are cross-sectional views illustrating MRAM devices according to one or more embodiments;

FIG. 9 is a cross-sectional view illustrating an MRAM device according to one or more embodiments; and

FIGS. 10, 11, 12, 13, 14, 15, 16, 17 and 18 are cross-sectional views illustrating a method of manufacturing an MRAM device, according to one or more embodiments.

### DETAILED DESCRIPTION

Hereinafter, embodiments of the disclosure will be described in detail with reference to the attached drawings. In the following description, like reference numerals refer to like elements throughout the specification.

As used herein, a plurality of “units”, “modules”, “members”, and “blocks” may be implemented as a single component, or a single “unit”, “module”, “member”, and “block” may include a plurality of components.

It will be understood that when an element is referred to as being “connected” with or to another element, it can be directly or indirectly connected to the other element.

Also, when a part “includes” or “comprises” an element, unless there is a particular description contrary thereto, the part may further include other elements, not excluding the other elements.

Throughout the description, when a member is “on” another member, this includes not only when the member is in contact with the other member, but also when there is another member between the two members.

Herein, the expressions “at least one of a, b or c” and “at least one of a, b and c” indicate “only a,” “only b,” “only c,” “both a and b,” “both a and c,” “both b and c,” and “all of a, b, and c.”

It will be understood that, although the terms “first”, “second”, “third”, etc., may be used herein to describe various elements, is the disclosure should not be limited by these terms. These terms are only used to distinguish one element from another element.

As used herein, the singular forms “a,” “an” and “the” are intended to include the plural forms as well, unless the context clearly indicates otherwise.

With regard to any method or process described herein, an identification code may be used for the convenience of the description but is not intended to illustrate the order of each step or operation. Each step or operation may be implemented in an order different from the illustrated order unless the context clearly indicates otherwise. One or more steps or operations may be omitted unless the context of the disclosure clearly indicates otherwise.

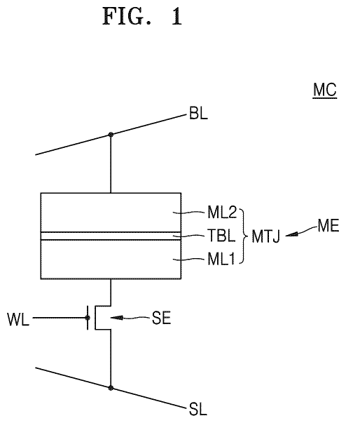

FIG. 1 is a circuit diagram of a unit memory cell MC of a magnetoresistive random access memory (MRAM) device according to one or more embodiments.

Referring to FIG. 1, the unit memory cell MC may include a memory element ME and a selection element SE. The memory element ME may be electrically connected to the selection element SE in series. The memory element ME may be connected between a bit line BL and the selection element SE. The selection element SE may be connected between the memory element ME and a source line SL and may be controlled by a word line WL. The selection element SE may include, for example, a bipolar transistor or a metal oxide semiconductor (MOS) field effect transistor.

The memory element ME may include a magnetic tunnel junction MTJ, which includes magnetic layers ML1 and ML2 apart from each other and a tunnel barrier TBL between the magnetic layers ML1 and ML2. One of the magnetic layers ML1 and ML2 may be a reference layer having a magnetization direction fixed to one direction regardless of an external magnetic field under a normal use environment. The other of the magnetic layers ML1 and ML2 may be a free layer of which the magnetization direction changes between two stable magnetization directions due to an external magnetic field or current. The electrical resistance of the magnetic tunnel junction MTJ may be much greater when the magnetization directions of the reference layer and the free layer are antiparallel to each other than when the magnetization directions of the reference layer and the free layer are parallel to each other. That is, the electrical resistance of the magnetic tunnel junction MTJ may be adjusted by changing the magnetization direction of the free layer. Accordingly, the memory element ME may store data in the unit memory cell MC by using the difference in electrical resistance according to the magnetization directions of the reference layer and the free layer.

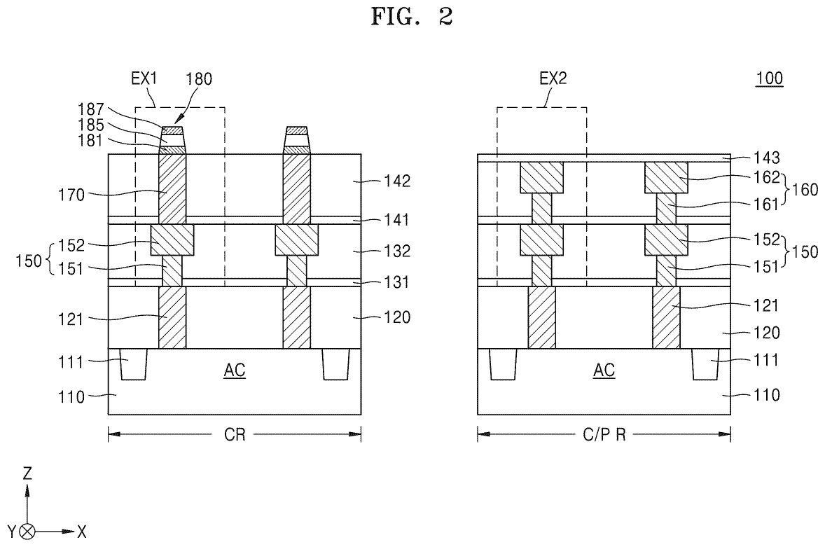

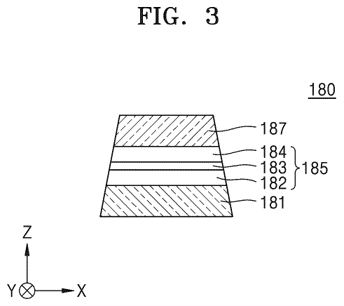

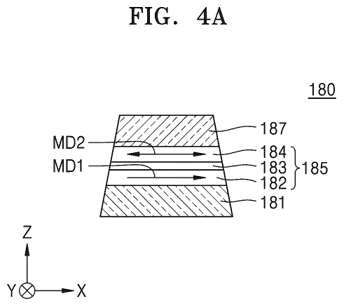

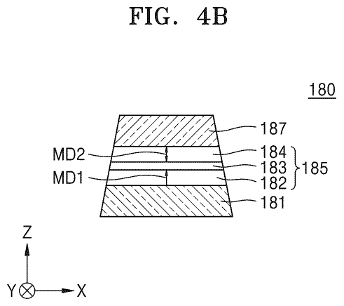

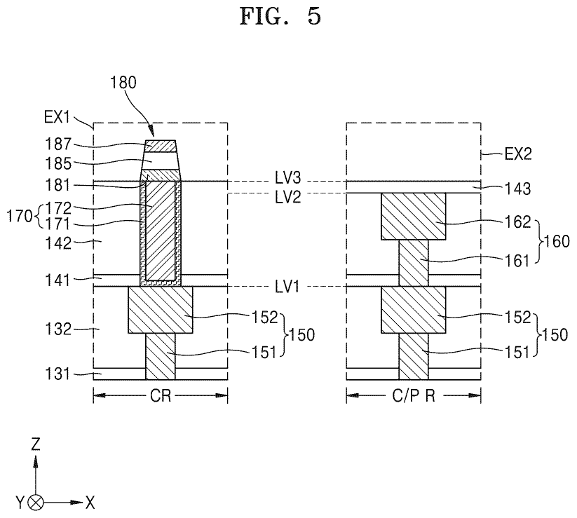

FIG. 2 is a cross-sectional view illustrating an MRAM device 100 according to one or more embodiments. FIG. 3 is a cross-sectional view illustrating an information storage structure 180 of the MRAM device 100 according to one or more embodiments. FIGS. 4A and 4B are cross-sectional views illustrating examples of the information storage structure 180 of the MRAM device 100 according to one or more embodiments. FIG. 5 is an enlarged cross-sectional view illustrating an area EX1 and an area EX2 of FIG. 2.

Referring to FIG. 2, the MRAM device 100 may include a substrate 110 including a cell region CR and a core/peripheral region C/P R. In the substrate 110, the cell region CR and the core/peripheral region C/P R may be arranged (i.e., offset relative to one another) in a first horizontal direction (an X direction).

The substrate 110 may include a semiconductor element, such as Si or Ge, or a compound semiconductor, such as SiC, GaAs, InAs, or InP. The substrate 110 may include a semiconductor substrate, at least one insulating layer formed on the semiconductor substrate, or/and structures including at least one conductive region. The conductive region may include, for example, a well doped with impurities or a structure doped with impurities. A device isolation layer 111 defining a plurality of active regions AC may be formed in the substrate 110. The device isolation layer 111 may include an oxide layer, a nitride layer, or a combination thereof. In one or more example embodiments, the device isolation layer 111 may have various structures, such as a shallow trench isolation (STI) structure.

On the cell region CR and core/peripheral region C/P R of the substrate 110, a lower interlayer insulating layer 120, a lower conductive region 121, a first etch stop layer 131, a first interlayer insulating layer 132, a second etch stop layer 141, and a second interlayer insulating layer 142 may be provided.

The lower interlayer insulating layer 120 may include an insulating layer including an oxide layer, a silicon nitride layer, or a combination thereof. The lower conductive region 121 may pass through the lower interlayer insulating layer 120 and be connected to the plurality of active regions AC of the substrate 110. The lower conductive region 121 may include various conductive regions, such as an interconnection layer, a contact plug, and a transistor. The lower conductive region 121 may include polysilicon, metal, conductive metal nitride, metal silicide, or a combination thereof.

The first etch stop layer 131 and the first interlayer insulating layer 132 may be disposed on the lower interlayer insulating layer 120. The first etch stop layer 131 may include a nitride, such as silicon nitride (SiN), silicon oxynitride (SiON), silicon carbonitride (SiCN), or silicon oxycarbonitride (SiOCN). The first interlayer insulating layer 132 may include an insulating layer including an oxide layer, a silicon nitride layer, or a combination thereof.

In the cell region CR and core/peripheral region C/P R, a first interconnection structure 150 passing through the first etch stop layer 131 and the first interlayer insulating layer 132 may be disposed. The first interconnection structure 150 may include a first interconnection via 151 and a first interconnection line 152. The first interconnection structure 150 may include at least one of metal and conductive metal nitride. For example, the first interconnection structure 150 may include copper.

The second etch stop layer 141 and the second interlayer insulating layer 142, which cover the first interlayer insulating layer 132, may be disposed in the cell region CR and core/peripheral region C/P R. The second etch stop layer 141 may include a nitride, such as SiN, SiON, SiCN, or SiOCN. The second interlayer insulating layer 142 may include an insulating layer including an oxide layer, a silicon nitride layer, or a combination thereof.

A lower electrode contact 170 may be disposed in the cell region CR. The lower electrode contact 170 may pass through the second etch stop layer 141 and the second interlayer insulating layer 142 and be connected to the first interconnection structure 150.

A second interconnection structure 160, which passes through the second etch stop layer 141 and the second interlayer insulating layer 142, may be disposed in the core/peripheral region C/P R. The second interconnection structure 160 may include a second interconnection via 161 and a second interconnection line 162. The second interconnection structure 160 may include at least one of metal and conductive metal nitride. For example, the second interconnection structure 160 may include copper.

In the core/peripheral region C/P R, an upper etch stop layer 143 may be disposed on the second interlayer insulating layer 142. The upper etch stop layer 143 may include a nitride, such as SiN, SiON, SiCN, or SiOCN. The upper etch stop layer 143 may cover the second interconnection structure 160, which passes through the second etch stop layer 141 and the second interlayer insulating layer 142.

Hereinafter, the first interconnection structure 150, the second interconnection structure 160, and the lower electrode contact 170 in the cell region CR and the core/peripheral region C/P R are described with reference to FIG. 5.

As illustrated in FIG. 5, the first interconnection structure 150 passing through the first interlayer insulating layer 132 and the lower electrode contact 170 passing through the second interlayer insulating layer 142 may be disposed in the cell region CR. The information storage structure 180 may be disposed on the lower electrode contact 170. The first interconnection structure 150 passing through the first interlayer insulating layer 132 and the second interconnection structure 160 passing through the second interlayer insulating layer 142 may be disposed in the core/peripheral region C/P R.

In one or more embodiments, the first interconnection structure 150, which passes through the first interlayer insulating layer 132 in the cell region CR and the core/peripheral region C/P R, may be disposed in the first interlayer insulating layer 132. Specifically, the first interconnection via 151 may extend through the first etch stop layer 131 into the first interlayer insulating layer 132, and the first interconnection line 152 may be disposed in the first interlayer insulating layer 132 on the first interconnection via 151.

In one or more embodiments, the vertical level of the upper surface of the first interlayer insulating layer 132 may be the same as the vertical level of the upper surface of the first interconnection structure 150. For example, the upper surface of the first interlayer insulating layer 132 may be at a first vertical level LV1 and the upper surface of the first interconnection structure 150 may be at the first vertical level LV1. For example, the upper surface of the first interconnection line 152 of the first interconnection structure 150 may be at the first vertical level LV1.

For example, the upper surface of the first interlayer insulating layer 132 may be coplanar with the upper surface of the first interconnection structure 150. For example, the upper surface of the first interlayer insulating layer 132 may be coplanar with the upper surface of the first interconnection line 152.

In one or more embodiments, the lower electrode contact 170 passing through the second interlayer insulating layer 142 in the cell region CR may be disposed in the second interlayer insulating layer 142. Specifically, the lower electrode contact 170 may pass through the second etch stop layer 141 and extend into the second interlayer insulating layer 142. For example, the lower electrode contact 170 may include portions respectively surrounded by the second etch stop layer 141 and the second interlayer insulating layer 142.

In one or more embodiments, the lower electrode contact 170 may include a first barrier pattern 171 and a first metal pattern 172. For example, the first barrier pattern 171 may include a metal nitride, such as tungsten nitride, tantalum nitride, or titanium nitride, and/or a metal, such as tantalum or titanium, and the first metal pattern 172 may include a metal material having low resistance, for example, tungsten, copper, or aluminum. As described above, the lower electrode contact 170 may be connected to the first interconnection structure 150.

In one or more embodiments, the lower electrode contact 170 may land on the first interconnection structure 150. Specifically, the lower electrode contact 170 may land on the first interconnection line 152 of the first interconnection structure 150. Accordingly, the lower surface of the lower electrode contact 170 may be at the first vertical level LV1.

In one or more embodiments, the second interconnection structure 160 passing through the second interlayer insulating layer 142 in the core/peripheral region C/P R may be disposed in the second interlayer insulating layer 142. Specifically, the second interconnection via 161 may extend through the second etch stop layer 141 into the second interlayer insulating layer 142, and the second interconnection line 162 may be disposed in the second interlayer insulating layer 142 on the second interconnection via 161.

In one or more embodiments, the second interconnection structure 160 in the core/peripheral region C/P R may be disposed on the first interconnection structure 150 and connected to the first interconnection structure 150. Specifically, the second interconnection via 161 of the second interconnection structure 160 may be disposed on the first interconnection line 152 of the first interconnection structure 150. The lower surface of the second interconnection structure 160 may be at the first vertical level LV1. For example, the lower surface of the second interconnection via 161 may be at the first vertical level LV1.

In one or more embodiments, the upper etch stop layer 143 covering the second interconnection structure 160 in the core/peripheral region C/P R may be disposed on the second interconnection structure 160. In one or more embodiments, the upper surface of the second interconnection structure 160 may be at a second vertical level LV2. In one or more embodiments, the upper surface of the lower electrode contact 170 may be at a third vertical level LV3 that is higher than the second vertical level LV2. In one or more embodiments, the upper surface of the upper etch stop layer 143 may be at the same vertical level as the upper surface of the lower electrode contact 170. For example, the upper surface of the upper etch stop layer 143 may be at the third vertical level LV3.

In one or more embodiments, the upper surface of the lower electrode contact 170 may be at a higher vertical level than the upper surface of the upper etch stop layer 143.

In one or more embodiments, the first interconnection structure 150 may be the uppermost interconnection structure in the cell region CR. Specifically, the first interconnection structure 150 may be the uppermost interconnection structure among a plurality of interconnection structures, which are disposed on the substrate 110 and under the lower electrode contact 170, in the cell region CR. For example, the first interconnection structure 150 may be the uppermost interconnection structure on which the lower electrode contact 170 lands (i.e., is in contact with). Specifically, the first interconnection line 152 may be the uppermost interconnection line in the cell region CR. For example, the first interconnection line 152 may be the uppermost interconnection line on which the lower electrode contact 170 lands (i.e., is in contact with).

In one or more embodiments, the first interconnection structure 150 may not be the uppermost interconnection structure in the core/peripheral region C/P R. In the core/peripheral region C/P R, the second interconnection structure 160 on the first interconnection structure 150 may be the uppermost interconnection structure. Specifically, in the core/peripheral region C/P R, the second interconnection structure 160 may be the uppermost interconnection structure among a plurality of interconnection structures disposed on the substrate 110 and at a vertical level that is the same as or lower than the vertical level of the information storage structure 180. Specifically, the second interconnection structure 160 may be the uppermost interconnection line in the core/peripheral region C/P R.

In one or more embodiments, the uppermost interconnection structure in the cell region CR and the uppermost interconnection structure in the core/peripheral region C/P R may be at different vertical levels. In other words, the first interconnection structure 150, which is the uppermost interconnection structure in the cell region CR, and the second interconnection structure 160, which is the uppermost interconnection structure in the core/peripheral region C/P R, may be at different vertical levels. That is, the uppermost interconnection structure in the cell region CR may be at a lower vertical level than the uppermost interconnection structure in the core/peripheral region C/P R.

In one or more embodiments, the lower electrode contact 170 in the cell region CR may overlap the second interconnection structure 160 in the core/peripheral region C/P R in the first horizontal direction (the X direction). For example, the lower electrode contact 170 in the cell region CR may overlap each of the second interconnection via 161 and the second interconnection line 162 in the core/peripheral region C/P R in the first horizontal direction (the X direction).

In one or more embodiments, the lower electrode contact 170 in the cell region CR may overlap the second etch stop layer 141 and the second interlayer insulating layer 142 in the core/peripheral region C/P R in the first horizontal direction (the X direction).

In one or more embodiments, the vertical height of the lower electrode contact 170 in the cell region CR may be greater than the vertical thickness of the second interlayer insulating layer 142. For example, the vertical height of the lower electrode contact 170 in the cell region CR may be greater than the sum of the vertical thicknesses of the second interlayer insulating layer 142 and the upper etch stop layer 143 in the core/peripheral region C/P R.

In one or more embodiments, the vertical thickness of the second interlayer insulating layer 142 in the cell region CR may be different from the vertical thickness of the second interlayer insulating layer 142 in the core/peripheral region C/P R. For example, the vertical level of the lower surface of the second interlayer insulating layer 142 in the cell region CR may be the same as the vertical level of the lower surface of the second interlayer insulating layer 142 in the core/peripheral region C/P R, while the vertical level of the upper surface of the second interlayer insulating layer 142 in the cell region CR may be different from the vertical level of the upper surface of the second interlayer insulating layer 142 in the core/peripheral region C/P R. For example, the upper surface of the second interlayer insulating layer 142 in the cell region CR may be at the third vertical level LV3, while the upper surface of the second interlayer insulating layer 142 in the core/peripheral region C/P R may be at the second vertical level LV2.

In one or more embodiments, for example, the upper surface of the second interlayer insulating layer 142 in the cell region CR may be at a vertical level that is higher than the third vertical level LV3.

In one or more embodiments, the vertical level of the lower surface of the lower electrode contact 170 in the cell region CR may be lower than the vertical level of the upper surface of the second interconnection structure 160 in the core/peripheral region C/P R. For example, the lower surface of the lower electrode contact 170 in the cell region CR may be at the first vertical level LV1, and the upper surface of the second interconnection structure 160 in the core/peripheral region C/P R may be at the second vertical level LV2. That is, the vertical level of the lower surface of the lower electrode contact 170 in the cell region CR may be lower than the vertical level of the upper surface of the uppermost interconnection structure in the core/peripheral region C/P R. That is, the vertical level of the lower surface of the lower electrode contact 170 in the cell region CR may be lower than the vertical level of the upper surface of the uppermost interconnection line in the core/peripheral region C/P R.

In one or more embodiments, the vertical level of the lower surface of the lower electrode contact 170 in the cell region CR may be lower than the vertical level of the upper surface of the second interlayer insulating layer 142 in the core/peripheral region C/P R. For example, the lower surface of the lower electrode contact 170 in the cell region CR may be at the first vertical level LV1, and the lower surface of the second interlayer insulating layer 142 in the core/peripheral region C/P R may be at the second vertical level LV2.

In one or more embodiments, the vertical level of the lower surface of the lower electrode contact 170 in the cell region CR may be lower than the vertical level of the upper surface of the upper etch stop layer 143 in the core/peripheral region C/P R. For example, the upper surface of the upper etch stop layer 143 may be at the third vertical level LV3.

On the cell region CR of the substrate 110, the information storage structure 180 may be provided on the lower electrode contact 170. The information storage structure 180 may not be provided on the core/peripheral region C/P R of the substrate 110. The information storage structure 180 may include a lower electrode 181, a magnetic tunnel junction structure 185, and an upper electrode 187. The magnetic tunnel junction structure 185 may correspond to the magnetic tunnel junction MTJ described with reference to FIG. 1. The lower electrode 181 and the upper electrode 187 may be apart from each other with the magnetic tunnel junction structure 185 therebetween. The lower electrode 181 may be disposed between the magnetic tunnel junction structure 185 and the lower electrode contact 170. The information storage structure 180 may be disposed on the lower electrode contact 170 and connected to the lower electrode 181.

Specifically, referring to FIG. 3, the information storage structure 180 may include a lower electrode 181, a magnetic tunnel junction structure 185, and an upper electrode 187. The magnetic tunnel junction structure 185 may include a first magnetic layer 182, a tunnel barrier layer 183, and a second magnetic layer 184, which are stacked on the lower electrode 181. The first magnetic layer 182, the tunnel barrier layer 183, and the second magnetic layer 184 may respectively correspond to the magnetic layer ML1, the tunnel barrier TBL, and the magnetic layer ML2, described with reference to FIG. 1.

The lower electrode 181 may include at least one of a metal, such as titanium or tantalum, and a metal nitride, such as titanium nitride or tantalum nitride. In one or more embodiments, the lower electrode 181 may include tungsten, copper, platinum, nickel, silver, gold, or the like. The upper electrode 187 may include at least one of a metal, such as titanium or tantalum, and a metal nitride, such as titanium nitride or tantalum nitride. In one or more embodiments, the upper electrode 187 may include tungsten, copper, platinum, nickel, silver, gold, or the like.

In one or more embodiments, the first magnetic layer 182 may be provided as a fixed layer having a fixed magnetization direction. Specifically, the first magnetic layer 182 may include a fixed pattern, a lower ferromagnetic pattern, an antiferromagnetic coupling spacer pattern, and an upper ferromagnetic pattern. In this case, the fixed pattern may include, for example, iron manganese (FeMn), iridium manganese (IrMn), platinum manganese (PtMn), manganese oxide (MnO), manganese sulfide (MnS), manganese tellurium (MnTe), manganese fluoride (MnF₂), iron fluoride (FeF₂), iron chloride (FeCl₂), iron oxide (FeO), cobalt chloride (CoCl₂), cobalt oxide (CoO), nickel chloride (NiCl₂), nickel oxide (NiO), or chromium (Cr). For example, the upper and lower ferromagnetic patterns may include a ferromagnetic material including at least one of iron (Fe), nickel (Ni), and cobalt (Co). For example, the antiferromagnetic coupling spacer pattern may include at least one of ruthenium (Ru), iridium (Ir), and rhodium (Rh).

In one or more embodiments, the second magnetic layer 184 may be provided as a free layer having a variable magnetization direction. In this case, the second magnetic layer 184 may include a ferromagnetic material, such as iron (Fe), cobalt (Co), nickel (Ni), chromium (Cr), or platinum (Pt). The second magnetic layer 184 may further include boron (B) or silicon (Si). These may be used alone or in combination of two or more. For example, the second magnetic layer 184 may include a composite material, such as CoFe, NiFe, FeCr, CoFeNi, PtCr, CoCrPt, CoFeB, NiFeSiB, or CoFeSiB.

In one or more embodiments, the tunnel barrier layer 183 may be disposed between the first magnetic layer 182 and the second magnetic layer 184. The first magnetic layer 182 and the second magnetic layer 184 may be apart from each other with the tunnel barrier layer 183 therebetween. The tunnel barrier layer 183 may include a metal oxide having insulating properties. For example, the tunnel barrier layer 183 may include magnesium oxide (MgOₓ) or aluminum oxide (AlOₓ).

In one or more embodiments, the second magnetic layer 184 may be disposed between the tunnel barrier layer 183 and the upper electrode 187 as an example, but the disclosure is not limited thereto. For example, the second magnetic layer 184 may be disposed between the tunnel barrier layer 183 and the lower electrode 181.

Referring to FIGS. 4A and 4B, the first magnetic layer 182 may have a first magnetization direction MD1 fixed in one direction, and the second magnetic layer 184 may have a second magnetization direction MD2 that may be changed to be parallel or anti-parallel to the first magnetization direction MD1 of the first magnetic layer 182.

As illustrated in FIG. 4A, the magnetization directions MD1 and MD2 of the first magnetic layer 182 and the second magnetic layer 184 may be parallel to the interface between the tunnel barrier layer 183 and the second magnetic layer 184. In this case, each of the first magnetic layer 182 and the second magnetic layer 184 may include a ferromagnetic material. The first magnetic layer 182 may further include an antiferromagnetic material to fix the magnetization direction of the ferromagnetic material in the first magnetic layer 182.

As illustrated in FIG. 4B, the magnetization directions MD1 and MD2 of the first magnetic layer 182 and the second magnetic layer 184 may be perpendicular to the interface between the tunnel barrier layer 183 and the second magnetic layer 184. In this case, each of the first magnetic layer 182 and the second magnetic layer 184 may include at least one of a perpendicular magnetic material (e.g., CoFeTb, CoFeGd, or CoFeDy), a perpendicular magnetic material having an L10 structure, CoPt having a hexagonal close packed lattice structure, and a perpendicular magnetic structure. The perpendicular magnetic material having the L10 structure may include at least one of FePt in the L10 structure, FePd in the L10 structure, CoPd in the L10 structure, or CoPt in the L10 structure. The perpendicular magnetic structure may include magnetic layers and non-magnetic layers, which are alternately and repeatedly stacked. As an example, the perpendicular magnetic structure may include at least one of (Co/Pt) n, (CoFe/Pt) n, (CoFe/Pd) n, (Co/Pd) n, (Co/Ni) n, (CoNi/Pt) n, (CoCr/Pt) n, and (CoCr/Pd) n (where n is the number of stacks).

In the cell region CR of the MRAM device 100 according to embodiments, the second interconnection structure 160 may not be present and the first interconnection structure 150 may be connected to the lower electrode contact 170, as the uppermost interconnection structure.

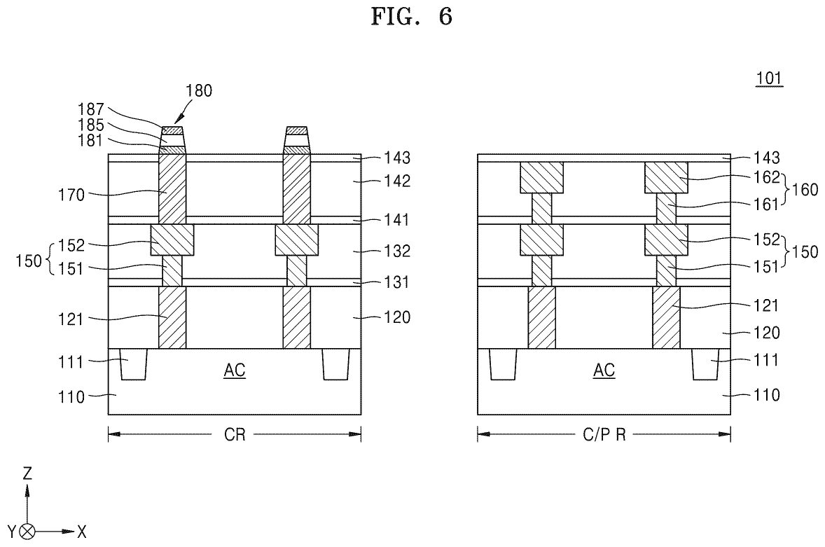

FIGS. 6 to 8 are cross-sectional views illustrating MRAM devices 101, 102, and 103 according to one or more embodiments. Hereinafter, the description will focus on the differences from the MRAM device 100 described with reference to FIGS. 2 and 3.

Referring to FIG. 6, the MRAM device 101 may include a lower conductive region 121, a first interconnection structure 150, a second interconnection structure 160, and/or a lower electrode contact 170, which are disposed on a substrate 110 including a cell region CR and a core/peripheral region C/P R.

In one or more embodiments, in the cell region CR, a lower interlayer insulating layer 120 and a lower conductive region 121 passing through the lower interlayer insulating layer 120, a first interlayer insulating layer 132 and a first interconnection structure 150 passing through the first interlayer insulating layer 132, and a second interlayer insulating layer 142 and a lower electrode contact 170 passing through the second interlayer insulating layer 142 may be disposed. The lower electrode contact 170 may be surrounded by a second etch stop layer 141 and the second interlayer insulating layer 142. In one or more embodiments, an upper etch stop layer 143 may be further disposed on the second interlayer insulating layer 142. The lower electrode contact 170 may further include a portion surrounded by the upper etch stop layer 143. The upper etch stop layer 143 in the cell region CR may be at the same vertical level as the upper etch stop layer 143 in the core/peripheral region C/P R.

In one or more embodiments, the vertical thickness of the second interlayer insulating layer 142 in the cell region CR may be the same as the vertical thickness of the second interlayer insulating layer 142 in the core/peripheral region C/P R. For example, the vertical level of the lower surface of the second interlayer insulating layer 142 in the cell region CR may be the same as the vertical level of the lower surface of the second interlayer insulating layer 142 in the core/peripheral region C/P R. For example, the vertical level of the upper surface of the second interlayer insulating layer 142 in the cell region CR may be the same as the vertical level of the upper surface of the second interlayer insulating layer 142 in the core/peripheral region C/P R.

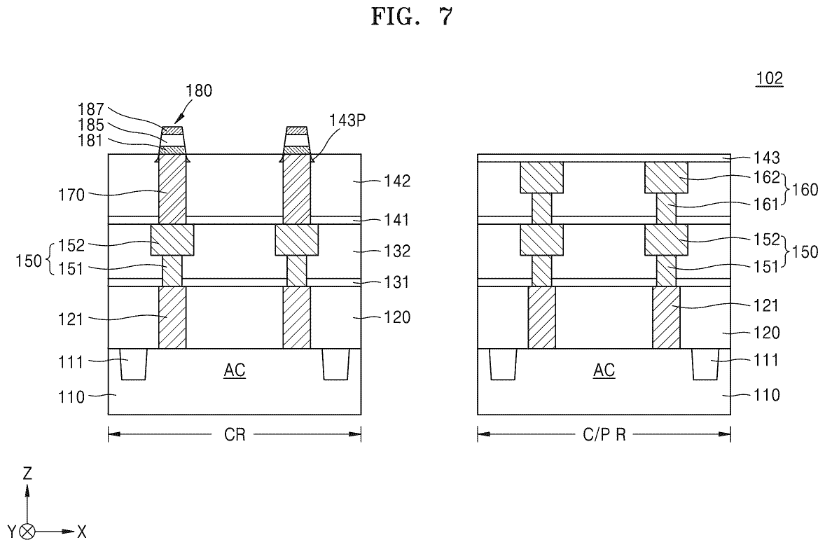

Referring to FIG. 7, the MRAM device 102 may include a lower conductive region 121, a first interconnection structure 150, a second interconnection structure 160, and/or a lower electrode contact 170, which are disposed on a substrate 110 including a cell region CR and a core/peripheral region C/P R.

In one or more embodiments, in the cell region CR, a lower interlayer insulating layer 120 and a lower conductive region 121 passing through the lower interlayer insulating layer 120, a first interlayer insulating layer 132 and a first interconnection structure passing through the first interlayer insulating layer 132, and a second interlayer insulating layer 142 and a lower electrode contact 170 passing through the second interlayer insulating layer 142 may be disposed. The lower electrode contact 170 may be surrounded by a second etch stop layer 141 and the second interlayer insulating layer 142.

In one or more embodiments, a portion 143P of an upper etch stop layer 143 may be disposed within the second interlayer insulating layer 142. The portion 143P may be formed as the upper etch stop layer 143 is disposed on the second interlayer insulating layer 142 and, while a subsequent process of forming the information storage structure 180 is in progress, the upper etch stop layer 143, except for the portion 143P, is removed and then a material constituting the second interlayer insulating layer 142 is applied.

In one or more embodiments, the vertical thickness of the second interlayer insulating layer 142 in the cell region CR may be different from the vertical thickness of the second interlayer insulating layer 142 in the core/peripheral region C/P R. For example, the upper surface of the second interlayer insulating layer 142 in the cell region CR may be at the third vertical level LV3 (see FIG. 5) or a level that is higher than the third vertical level LV3, while the upper surface of the second interlayer insulating layer 142 in the core/peripheral region C/P R may be at the second vertical level LV2 (see FIG. 5).

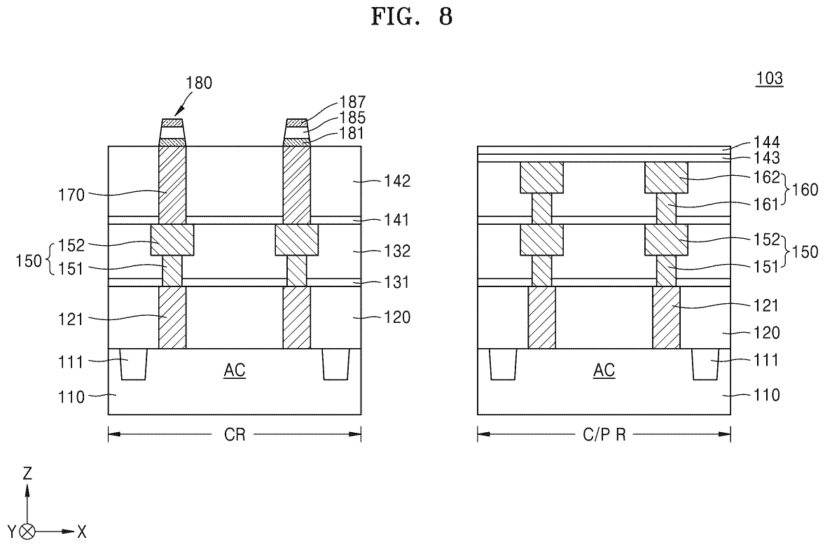

Referring to FIG. 8, the MRAM device 103 may include a lower conductive region 121, a first interconnection structure 150, a second interconnection structure 160, and/or a lower electrode contact 170, which are disposed on a substrate 110 including a cell region CR and a core/peripheral region C/P R.

In one or more embodiments, in the cell region CR, a lower interlayer insulating layer 120 and a lower conductive region 121 passing through the lower interlayer insulating layer 120, a first interlayer insulating layer 132 and a first interconnection structure passing through the first interlayer insulating layer 132, and a second interlayer insulating layer 142 and a lower electrode contact 170 passing through the second interlayer insulating layer 142 may be disposed. The lower electrode contact 170 may be surrounded by a second etch stop layer 141 and the second interlayer insulating layer 142.

In one or more embodiments, in the core/peripheral region C/P R, an upper insulating layer 144 may be further disposed on an upper etch stop layer 143. For example, the upper insulating layer 144 may include an oxide layer, a silicon nitride layer, or a combination thereof.

In one or more embodiments, the upper surface of the second interlayer insulating layer 142 in the cell region CR may be at a higher vertical level than the upper surface of the upper etch stop layer 143 in the core/peripheral region C/P R. The upper surface of the second interlayer insulating layer 142 in the cell region CR may be at the same vertical level as the upper surface of the upper insulating layer 144 on the core/peripheral region C/P R.

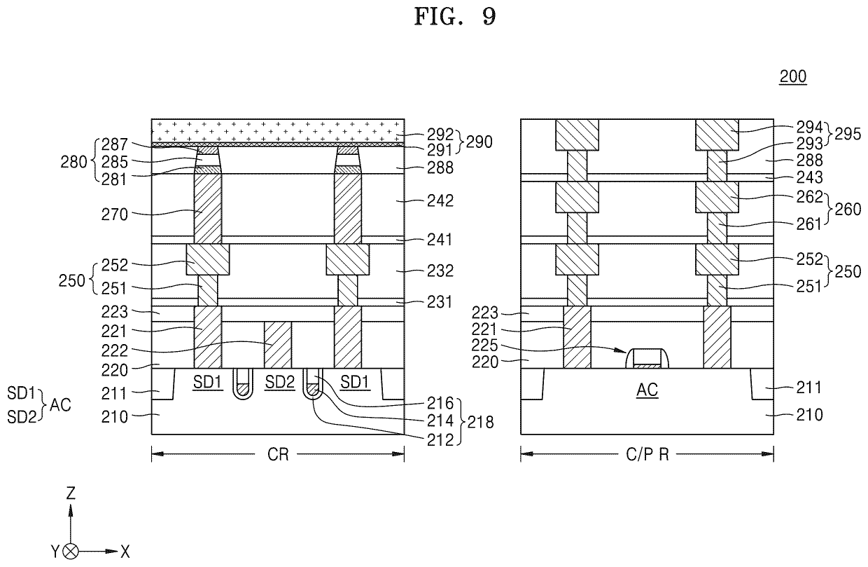

FIG. 9 is a cross-sectional view illustrating an MRAM device 200 according to one or more embodiments.

Referring to FIG. 9, the MRAM device 200 may include a substrate 210 including a cell region CR and a core/peripheral region C/P R. On the substrate 210, the cell region CR and the core/peripheral region C/P R may be arranged (i.e., offset relative to one another) in a first horizontal direction (an X direction). A device isolation layer 211 may be provided in the substrate 210 to define an active region AC.

A cell gate structure 218 may be provided in the cell region CR of the substrate 210. In an embodiment, the cell gate structure 218 may be a buried gate structure in which a gate line 214 is disposed inside a trench formed in the substrate 210. The gate line 214 may correspond to the word line WL described with reference to FIG. 1.

The cell gate structure 218 may include a gate dielectric layer 212 covering the inner wall and bottom of the trench in which the cell gate structure 218 is formed, the gate line 214 extending in a second horizontal direction (a Y direction) within the substrate 210, and a buried insulating layer 216 on the gate line 214.

The gate dielectric layer 212 may include at least one selected from silicon oxide, silicon nitride, silicon oxynitride, oxide/nitride/oxide (ONO), and a high-k dielectric material having a higher dielectric constant than silicon oxide. For example, the gate dielectric layer 212 may have a dielectric constant of about 10 to about 25. In one or more embodiments, the gate dielectric layer 212 may include at least one material selected from hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), strontium titanium oxide (SrTiO), yttrium oxide (YO), aluminum oxide (AlO), and lead scandium tantalum oxide (PbScTaO). For example, the gate dielectric layer 212 may include HfO₂, Al₂O₃, HfAlO₃, Ta₂O₃, or TiO₂.

The gate line 214 may include a metal material or conductive metal nitride, such as Ti, TiN, Ta, or TaN. The gate line 214 may include doped polysilicon, a metal material such as W, a conductive metal nitride such as WN, TiSiN, or WSiN, or a combination thereof.

The buried insulating layer 216 may include at least one material selected from silicon oxide, silicon nitride, silicon oxynitride, and a combination thereof.

A first impurity region SD1 and a second impurity region SD2 may be provided on both sides of the cell gate structure 218, respectively. In one or more embodiments, the first impurity region SD1 may be a drain region and the second impurity region SD2 may be a source region. The cell gate structure 218, the first impurity region SD1, and the second impurity region SD2 may form a cell transistor.

A core/peripheral transistor 225 may be provided in the core/peripheral region C/P R of the substrate 210. In one or more embodiments, the core/peripheral transistor 225 may be a planar-type transistor.

A lower first interlayer insulating layer 220 and a lower second interlayer insulating layer 223, which cover the cell transistor and the core/peripheral transistor 225, may be disposed on the substrate 210. The lower first interlayer insulating layer 220 and the lower second interlayer insulating layer 223 may form the lower interlayer insulating layer 120 described with reference to FIG. 2.

A contact plug 221, which passes through the lower first interlayer insulating layer 220 and the lower second interlayer insulating layer 223, may be disposed in the cell region CR. The contact plug 221 may be connected to the first impurity region SD1 and may extend within the lower first interlayer insulating layer 220 and the lower second interlayer insulating layer 223. A source contact 222 passing through the lower first interlayer insulating layer 220 may be disposed in the cell region CR. The source contact 222 may be connected to the second impurity region SD2 and may extend within the lower first interlayer insulating layer 220.

In the core/peripheral region C/P R, a contact plug 221, which passes through the lower first interlayer insulating layer 220 and the lower second interlayer insulating layer 223, may be disposed. The contact plug 221 may be connected to the active region AC and may extend within the lower first interlayer insulating layer 220 and the lower second interlayer insulating layer 223.

The cell transistor, the core/peripheral transistor 225, the contact plug 221, and the source contact 222 may form the lower conductive region 121 described with reference to FIG. 2.

In the cell region CR, a first interconnection structure 250 and a lower electrode contact 270 may be disposed on the contact plug 221. The first interconnection structure 250 may be similar to first interconnection structure 150, and may include first interconnection vias 251 and first interconnection lines 252. One or more of the first interconnection lines 252 disposed in the cell region may also be referred to as cell interconnection lines. The lower electrode contact 270 may pass through a second etch stop layer 241 and a second interlayer insulating layer 242 and be connected to the first interconnection structure 250. The first interconnection structure 250 may pass through a first etch stop layer 231 and a first interlayer insulating layer 232 and be connected to the contact plug 221. The lower electrode contact 270 and the first interconnection structure 250 may be connected to the first impurity region SD1 through the contact plug 221. The lower electrode contact 270 and the first interconnection structure 250 may be connected to the cell transistor through the contact plug 221.

In the core/peripheral region C/P R, the first interconnection structure 250 and the second interconnection structure 260 may be disposed on the contact plug 221. The second interconnection structure 260 may be similar to second interconnection structure 160, and may include first interconnection vias 261 and second interconnection lines 262. The second interconnection structure 260 may pass through the second etch stop layer 241 and the second interlayer insulating layer 242 and be connected to the first interconnection structure 250. The first interconnection structure 250 may pass through the first etch stop layer 231 and the first interlayer insulating layer 232 and be connected to the contact plug 221. The first interconnection structure 250 and the second interconnection structure 260 may be connected to the active region AC through the contact plug 221. The first interconnection structure 250 and the second interconnection structure 260 may be connected to the core/peripheral transistor 225 through the contact plug 221. One or more of the first interconnection lines 252 disposed in the core/peripheral region C/P R, the second interconnection lines 262, and the upper interconnection lines 294 may be collectively referred to as core peripheral interconnection lines.

In the cell region CR, an information storage structure 280 may be disposed on the lower electrode contact 270. The information storage structure 280 may be similar to information storage structure 180 and may include a lower electrode 281, a magnetic tunnel junction structure 285, and an upper electrode 287. The information storage structure 280 may pass through an upper interlayer insulating layer 288 and be connected to the lower electrode contact 270. The upper interlayer insulating layer 288 may include an oxide layer, a silicon nitride layer, or a combination thereof.

A bit line 290 may be provided on the information storage structure 280. In one or more embodiments, the bit line 290 may extend in the first horizontal direction (the X direction). The bit line 290 may include a second barrier pattern 291 and a second metal pattern 292. For example, the second barrier pattern 291 may include a metal nitride, such as tungsten nitride, tantalum nitride, or titanium nitride, and/or a metal, such as tantalum or titanium, and the second metal pattern 292 may include tungsten, copper, or aluminum. The bit line 290 may correspond to the bit line BL described with reference to FIG. 1.

An upper interconnection structure 295 may be disposed on the second interconnection structure 260 in the core/peripheral region C/P R. The upper interconnection structure 295 may be connected to the second interconnection structure 260 by passing through an upper etch stop layer 243 and the upper interlayer insulating layer 288. The upper interconnection structure 295 may include an upper interconnection via 293 and an upper interconnection line 294.

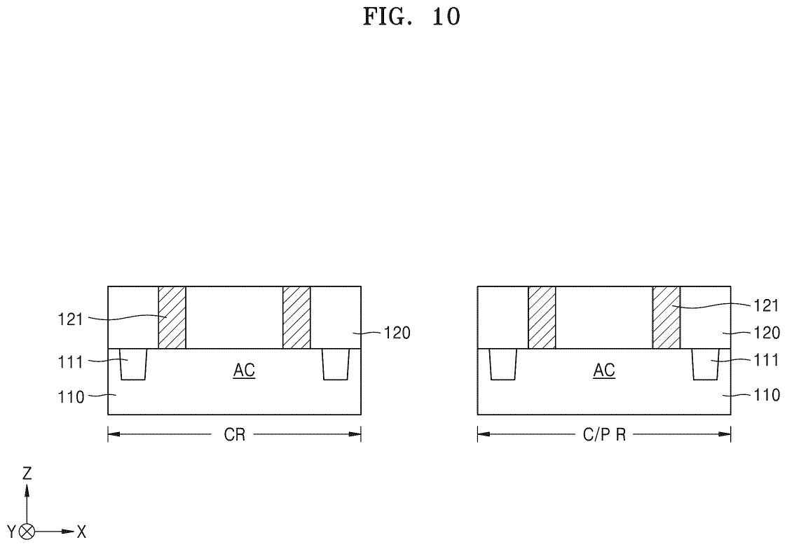

FIGS. 10 to 18 are cross-sectional views illustrating a method of manufacturing the MRAM device 100, according to embodiments.

Referring to FIG. 10, a substrate 110 including a cell region CR and a core/peripheral region C/P R may be provided. A device isolation layer 111 may be formed in the substrate 110. On the substrate 110, a lower interlayer insulating layer 120 and a lower conductive region 121 passing through the lower interlayer insulating layer 120 may be formed. The lower interlayer insulating layer 120 and the lower conductive region 121 may be formed through the same process in the cell region CR and core/peripheral region C/P R. The lower interlayer insulating layer 120 and the lower conductive region 121 may be at the same vertical level in the cell region CR and the core/peripheral region C/P R.

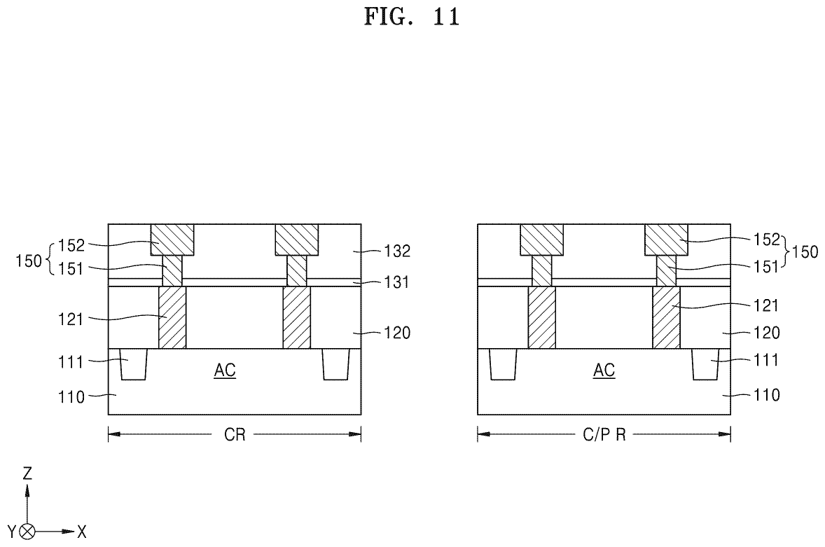

Referring to FIG. 11, a first etch stop layer 131, a first interlayer insulating layer 132, and a first interconnection structure 150 passing through the first etch stop layer 131 and the first interlayer insulating layer 132 may be formed on the lower interlayer insulating layer 120. Specifically, the first etch stop layer 131 and the first interlayer insulating layer 132 may be sequentially formed, and a first interconnection via 151 and a first interconnection line 152 may be sequentially formed.

The first etch stop layer 131, the first interlayer insulating layer 132, and the first interconnection structure 150 passing through the first etch stop layer 131 and the first interlayer insulating layer 132 may be formed in the cell region CR and core/peripheral region C/P R. The first etch stop layer 131, the first interlayer insulating layer 132, and the first interconnection structure 150 passing through the first etch stop layer 131 and the first interlayer insulating layer 132 may be at the same vertical level in the cell region CR and the core/peripheral region C/P R.

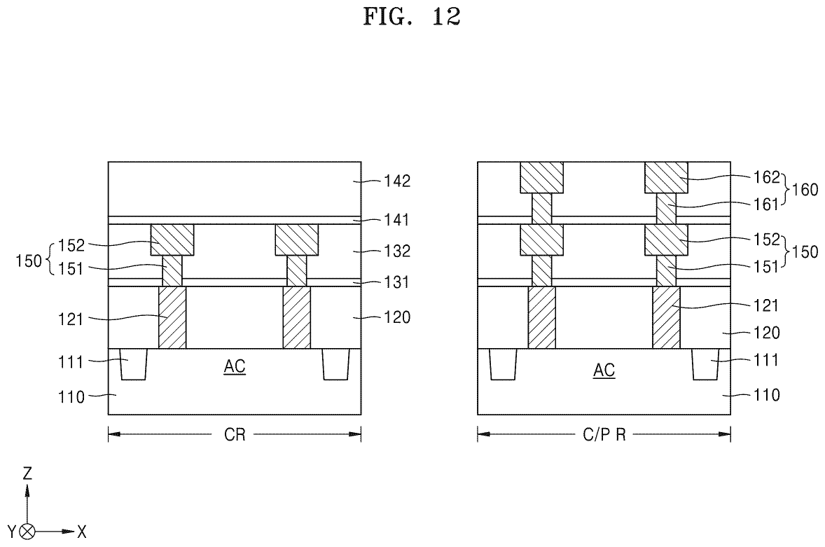

Referring to FIG. 12, a second etch stop layer 141 and a second interlayer insulating layer 142 may be formed on the first interlayer insulating layer 132. The second etch stop layer 141 and the second interlayer insulating layer 142 may be formed through the same process in the cell region CR and core/peripheral region C/P R. The second etch stop layer 141 and the second interlayer insulating layer 142 may be at the same vertical level in the cell region CR and the core/peripheral region C/P R.

Thereafter, a second interconnection structure 160, which passes through the second etch stop layer 141 and the second interlayer insulating layer 142, may be formed in the core/peripheral region C/P R. The second interconnection structure 160 may not be formed in the cell region CR. Specifically, the second etch stop layer 141 and the second interlayer insulating layer 142 may be sequentially formed in the core/peripheral region C/P R, and a second interconnection via 161 and a second interconnection line 162 may be sequentially formed.

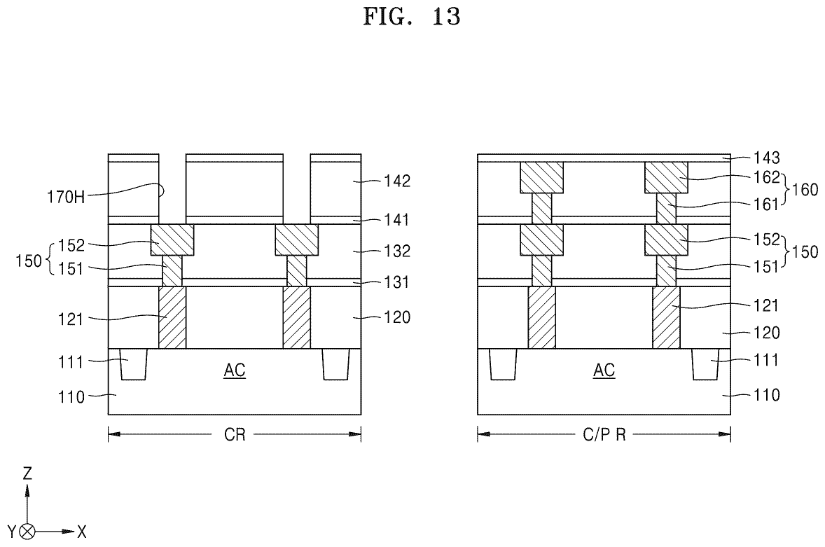

Referring to FIG. 13, in the cell region CR and core/peripheral region C/P R, an upper etch stop layer 143 may be formed on the second interlayer insulating layer 142. The upper etch stop layer 143 may be at the same vertical level in the cell region CR and the core/peripheral region C/P R. In some other embodiments, an upper insulating layer 144 (see FIG. 8) may be further formed on the upper etch stop layer 143.

Thereafter, a lower electrode contact hole 170H may be formed in the cell region CR, the lower electrode contact hole 170H sequentially passing through the upper etch stop layer 143, the second interlayer insulating layer 142, and the second etch stop layer 141. In the cell region CR, the first interconnection line 152 of the first interconnection structure 150 may be exposed by the lower electrode contact hole 170H.

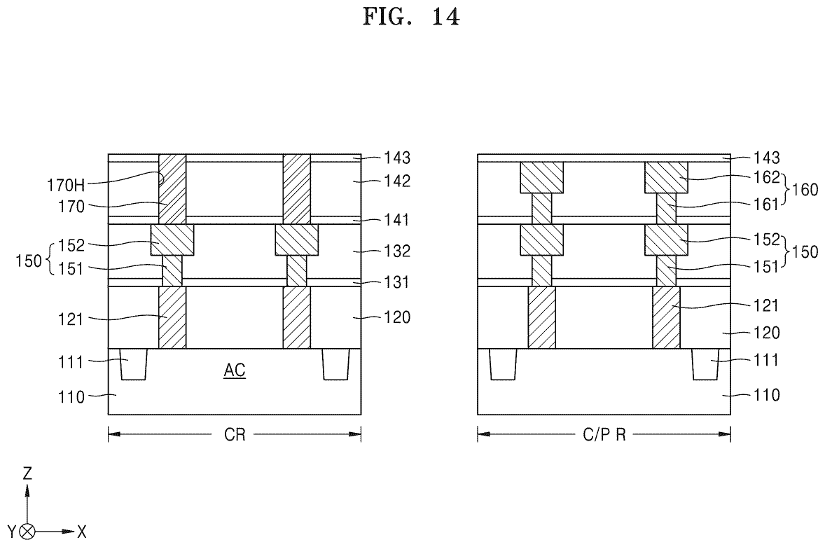

Referring to FIG. 14, in the cell region CR, a lower electrode contact 170 may be formed to fill the lower electrode contact hole 170H.

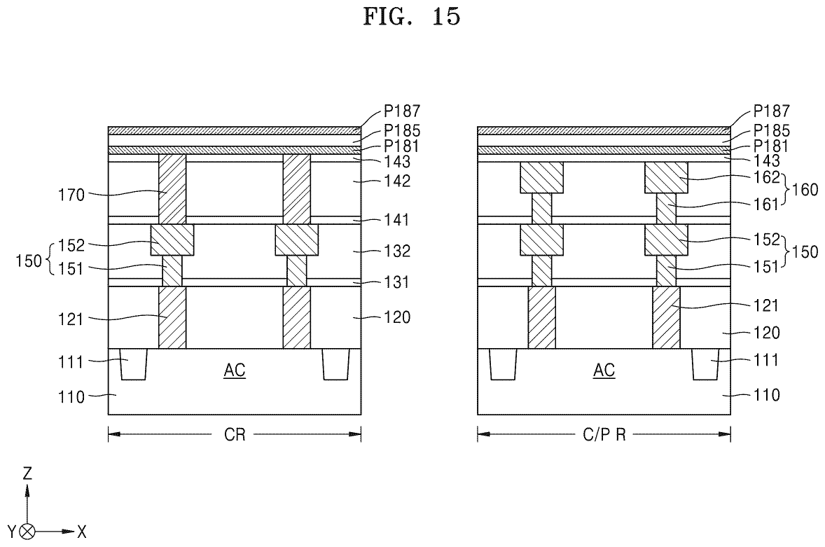

Referring to FIG. 15, in the cell region CR and core/peripheral region C/P R, a free first electrode layer P181, a free magnetic tunnel junction layer P185, and a free second electrode layer P187 may be sequentially formed on the lower electrode contact 170.

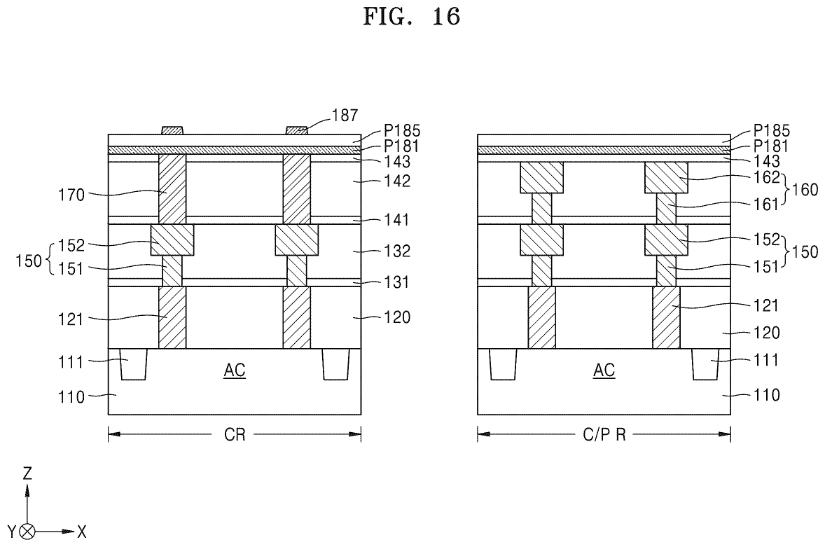

Referring to FIG. 16, in the cell region CR, an upper electrode 187 may be formed by removing a portion of the free second electrode layer P187. In this case, in the core/peripheral region C/P R, the free second electrode layer P187 may be removed to expose the free magnetic tunnel junction layer P185.

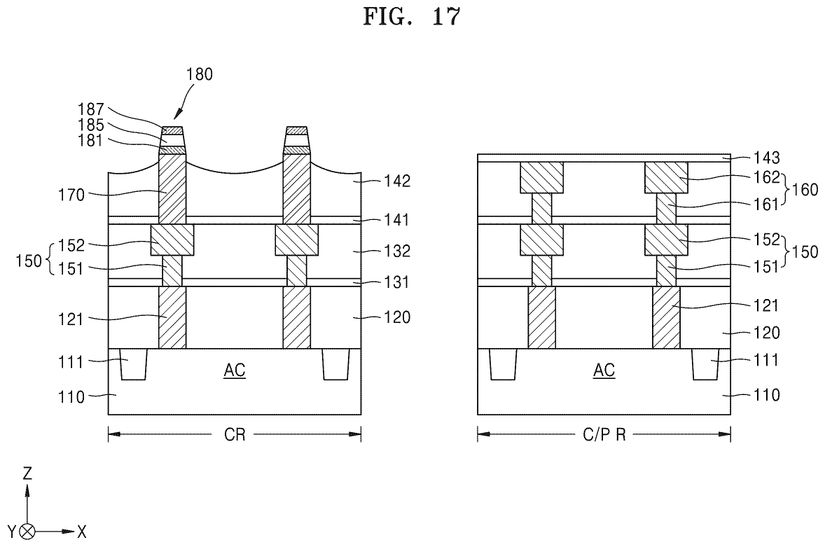

Referring to FIG. 17, in the cell region CR, a lower electrode 181 and a magnetic tunnel junction structure 185 may be formed by etching portions of the free first electrode layer P181 and the free magnetic tunnel junction layer P185. Etching the portions of the free first electrode layer P181 and the free magnetic tunnel junction layer P185 may include using the upper electrode 187 as an etch mask.

In one or more embodiments, forming the lower electrode 181 and the magnetic tunnel junction structure 185 by removing portions of the free first electrode layer P181 and the free magnetic tunnel junction layer P185 may be performed using an ion beam etching (IBE) process. When removing portions of the free first electrode layer P181 and the free magnetic tunnel junction layer P185, portions of the upper etch stop layer 143 and the second interlayer insulating layer 142 surrounding a portion of the lower electrode contact 170 may also be removed.

In the cell region CR, when removing portions of the free first electrode layer P181 and the free magnetic tunnel junction layer P185, in the core/peripheral region C/P R, the free magnetic tunnel junction layer P185 and the free second electrode layer P187 may be removed, while the upper etch stop layer 143 and the second interlayer insulating layer 142 may not be removed. To this end, a cover block may be formed on the upper etch stop layer 143 during the etching process. The cover block may be removed later.

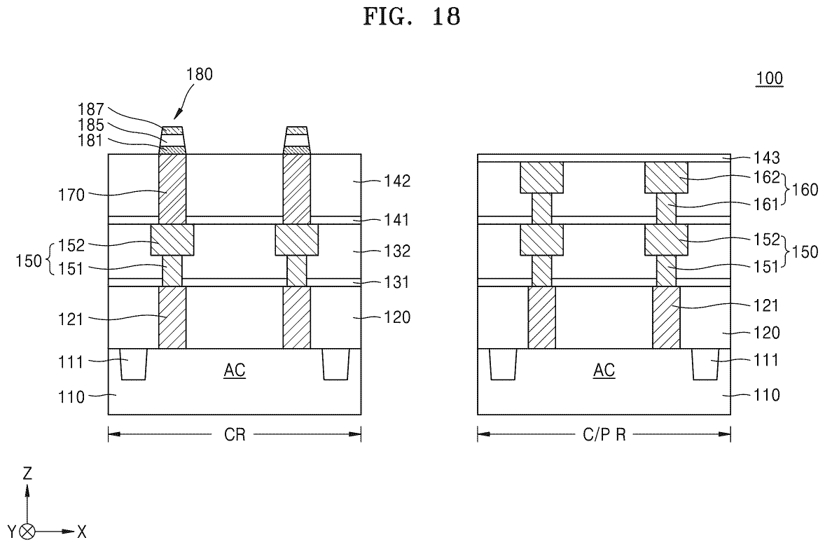

Referring to FIG. 18, in the cell region CR, the second interlayer insulating layer 142 surrounding an upper portion of the lower electrode contact 170 may be formed again. As a result, the MRAM device 100 may be formed.

In one or more embodiments according to the technical idea of the disclosure, as described above, in the cell region CR, the second interconnection structure 160 may not be present and the first interconnection structure 150 may be connected to the lower electrode contact 170, as the uppermost interconnection structure. As a result, when the portions of the free first electrode layer P181 and the free magnetic tunnel junction layer P185 are removed and the portions of the upper etch stop layer 143 and the second interlayer insulating layer 142 are also removed, the first interconnection structure 150 may not be exposed. In other words, in embodiments according to the technical idea of the disclosure, as, in the cell region CR, the first interconnection structure 150 as the uppermost interconnection structure is connected to the lower electrode contact 170, the lower electrode contact 170 may secure a sufficient vertical height, and thus, a lower interconnection structure may not be exposed during the IBE process. In a comparative example, when the second interconnection structure 160 is disposed in the cell region CR, as in the core/peripheral region C/P R, under the lower electrode contact 170 and connected to the lower electrode contact 170, the second interconnection structure may be exposed and cause defects when the portions of the free first electrode layer P181 and the free magnetic tunnel junction layer P185 are removed and the portions of the upper etch stop layer 143 and the second interlayer insulating layer 142 are also removed. That is, according to embodiments according to the technical idea of the disclosure, the MRAM device 100 having improved performance and reliability may be provided.

In one or more embodiments according to the technical idea of the disclosure, as the lower electrode contact 170 secures a sufficient vertical height, a key open mask process may be skipped in the process for manufacturing the MRAM device 100. Specifically, in the comparative example in which the lower electrode contact 170 does not secure a sufficient vertical height, a key open mask process has to be performed to align a key for the lower electrode contact 170. That is, according to embodiments according to the technical idea of the disclosure, the MRAM device 100 having a reduced manufacturing process may be provided.

While the disclosure has been particularly shown and described with reference to embodiments thereof, it will be understood that various changes in form and details may be made therein without departing from the spirit and scope of the following claims.

What is claimed is:

1. A magnetoresistive random access memory (MRAM) device comprising:
a cell region on a substrate;
a core peripheral region on the substrate and adjacent from the cell region in a horizontal direction;
a first interlayer insulating layer in the cell region and the core peripheral region;
a second interlayer insulating layer on the first interlayer insulating layer;
a first interconnection line in the first interlayer insulating layer, wherein the first interconnection line is in the cell region and the core peripheral region;
a second interconnection line in the second interlayer insulating layer, wherein the second interconnection line is in the core peripheral region and is connected to the first interconnection line;
a lower electrode contacts on the first interconnection line in the cell region; and
a magnetic tunnel junction structure on the lower electrode contact,
wherein the lower electrode contact and the second interconnection line overlap each other in the horizontal direction.

2. The MRAM device of claim 1, wherein the second interconnection line is above the first interconnection line in the core peripheral region, and an upper surface of the second interconnection line is at a vertical level that is the same as or lower than a vertical level of a lower surface of the magnetic tunnel junction structure.

3. The MRAM device of claim 1, wherein the lower electrode contact is in contact with the first interconnection line.

4. The MRAM device of claim 1, further comprising:
a lower electrode between the lower electrode contact and the magnetic tunnel junction structure; and
an upper electrode spaced apart from the lower electrode, wherein the magnetic tunnel junction structure is between the lower electrode and the upper electrode.

5. The MRAM device of claim 1, wherein an upper surface of the first interlayer insulating layer is coplanar with an upper surface of the first interconnection line.

6. The MRAM device of claim 1, further comprising an interconnection via connecting the second interconnection line to the first interconnection line,
wherein the interconnection via is surrounded by the second interlayer insulating layer, and
wherein the interconnection via overlaps the lower electrode contact in the horizontal direction.

7. The MRAM device of claim 6, further comprising an etch stop layer between the first interlayer insulating layer and the second interlayer insulating layer,
wherein a portion of the lower electrode contact is surrounded by the etch stop layer.

8. The MRAM device of claim 1, wherein a vertical thickness of the lower electrode contact is greater than a vertical thickness of the second interlayer insulating layer.

9. The MRAM device of claim 1, wherein the lower electrode contact passes through the second interlayer insulating layer.

10. A magnetoresistive random access memory (MRAM) device comprising:
a cell region on a substrate;
a core peripheral region on the substrate and adjacent from the cell region in a horizontal direction;
a cell transistor in the cell region;
a core peripheral transistor in the core peripheral region;
a cell interconnection line in the cell region, wherein the cell interconnection line is connected to the cell transistor;
a core peripheral interconnection line in the core peripheral region, wherein the core peripheral interconnection line is connected to the core peripheral transistor;
a lower electrode contact connected to the cell interconnection line; and
a magnetic tunnel junction structure on the lower electrode contact,
wherein an upper surface of each of the cell interconnection line and the core peripheral interconnection line is at a vertical level that is the same as or lower than a vertical level of a lower surface of the magnetic tunnel junction structure, and
wherein a vertical level of at least a portion of the core peripheral interconnection line overlaps a vertical level of the lower electrode contact.

11. The MRAM device of claim 10, further comprising:
a plurality of cell interconnection lines in the cell region including the cell interconnection line, wherein the plurality of cell interconnection lines are connected to the cell transistor; and
a plurality of core peripheral interconnection lines in the core peripheral region including the core peripheral interconnection line, wherein the plurality of core peripheral interconnection lines are connected to the core peripheral transistor,
wherein a vertical level of an uppermost cell interconnection line among the plurality of cell interconnection lines is lower than a vertical level of an uppermost core peripheral interconnection line among the plurality of core peripheral interconnection lines.

12. The MRAM device of claim 11, wherein the lower electrode contact is in contact with the uppermost cell interconnection line.

13. The MRAM device of claim 10, further comprising:
a lower electrode between the lower electrode contact and the magnetic tunnel junction structure; and
an upper electrode spaced apart from the lower electrode, wherein the magnetic tunnel junction structure is between the lower electrode and the upper electrode.

14. The MRAM device of claim 10, further comprising:
a plurality of core peripheral interconnection lines in the core peripheral region including the core peripheral interconnection line, wherein the plurality of core peripheral interconnection lines are connected to the core peripheral transistor,
wherein a vertical level of a lower surface of the lower electrode contact is lower than a vertical level of an upper surface of an uppermost core peripheral interconnection line among the plurality of core peripheral interconnection lines.

15. The MRAM device of claim 10, further comprising an interlayer insulating layer through which the core peripheral interconnection line passes,
wherein a vertical level of an upper surface of the interlayer insulating layer is higher than a vertical level of a lower surface of the lower electrode contact.

16. The MRAM device of claim 10, further comprising:
a cell contact plug connecting the cell interconnection line to the cell transistor; and
a core peripheral contact plug connecting the core peripheral interconnection line to the core peripheral transistor.

17. The MRAM device of claim 10, further comprising a bit line on the magnetic tunnel junction structure.

18. A magnetoresistive random access memory (MRAM) device comprising:
a cell region on a substrate;
a core peripheral region on the substrate and adjacent from the cell region in a horizontal direction;
a cell transistor in the cell region;
a core peripheral transistor in the core peripheral region;
a cell interlayer insulating layer on the cell transistor;
a core peripheral interlayer insulating layer on the core peripheral transistor;
a plurality of cell interconnection lines connected to the cell transistor;
a plurality of core peripheral interconnection lines connected to the core peripheral transistor;
a lower electrode contact on an uppermost cell interconnection line among the plurality of cell interconnection lines;
an information storage structure on the lower electrode contact, the information storage structure comprising a lower electrode, a magnetic tunnel junction structure, and an upper electrode, wherein the lower electrode, the magnetic tunnel junction structure, and the upper electrode are sequentially stacked; and
a bit line on the information storage structure,
wherein the plurality of cell interconnection lines pass through the cell interlayer insulating layer at a vertical level that is the same as or lower than a vertical level of a lower surface of the magnetic tunnel junction structure,
wherein the plurality of core peripheral interconnection lines pass through the core peripheral interlayer insulating layer at a vertical level that is same as or lower than the vertical level of the lower surface of the magnetic tunnel junction structure, and
wherein the lower electrode contact overlaps an uppermost core peripheral interconnection line among the plurality of core peripheral interconnection lines in the horizontal direction.

19. The MRAM device of claim 18, wherein the lower electrode contact is in contact with the uppermost cell interconnection line.

20. The MRAM device of claim 18, wherein a vertical level of the uppermost cell interconnection line is lower than a vertical level of the uppermost core peripheral interconnection line.
